(19) United States
(12) Patent Application Publication
(10) Pub. No.: US 2026/0359507 A1
(43) Pub. Date: Nov. 12, 2026

(54) METHOD AND MACHINE CONTROLLER FOR MONITORING THE TEMPERATURE OF AN ELECTROMECHANICAL MACHINE

(71) Applicant: SIEMENS AKTIENGESELLSCHAFT, München (DE)

(72) Inventors: Mohamed Khalil, München (DE); Vincent Malik, München (DE); Meinhard Paffrath, Feldkirchen (DE); Juan Manuel Lorenzi, München (DE); Benjamin Amschler, Heinersreuth (DE); Christian Andreas Wolf Pozzo, Zimdorf (DE)

(21) Appl. No.: 19/120,837

(22) PCT Filed: Sep. 26, 2023
(86) PCT No.: PCT/EP2023/076470

§ 371 Date: Apr. 14, 2025

(30) Foreign Application Priority Data
Oct. 28, 2022 (EP) 22204504.9

(51) Int. Cl. G06F 30/17; G06F 11/30

(52) U.S. Cl. CPC G06F 30/17; G06F 11/3013; G06F 11/3058

(57) ABSTRACT

Structural data relating to geometry, heat conductivity and electrical conductivity of elements of the machine to be monitored are provided. Predefined temperature-critical points are located on the machine in relation to the structural data. A first thermal simulation model including a plurality of spatially resolved trial functions, a plurality of temperature curves are simulated in the machine in a spatially resolved manner. A reduced thermal simulation model with a reduced plurality of trial functions is generated and adjusted in such a way that it reproduces the temperature curves at the temperature-critical points. During operation of the machine, electrical operating data of the machine is recorded and, electrical energy losses in the machine are continuously simulated by an electrical simulation model of the machine in a spatially resolved manner. Based on the structural data and the simulated electrical energy losses, temperatures at the temperature-critical points are continuously determined.

Safe operation of electromechanical machines, such as electric motors, for example, in many cases requires the temperature of critical machine components or temperature-critical points of the machine to be monitored, in particular in the higher power range. By way of example, the insulation of a stator winding of an electric motor should therefore not be exposed to relatively high temperatures so as not to jeopardize their function.

The temperatures of many temperature-critical points or machine components are, however, not able to be measured directly, or are able to be measured directly only with difficulty. Therefore, it is generally technically very complex to install temperature sensors on a rotor of a motor and to transport sensor signals from there to a monitoring apparatus.

Historical operating data of a machine are often used in order to nevertheless at least obtain estimates with respect to operating temperatures that are to be expected. For this purpose, however, large amounts of historical operating data for the machine in question are generally required, which cover a plurality of operating conditions.

It is furthermore known to evaluate measured values from temperature sensors that are attached to more easily accessible points of the machine to be monitored. On the basis of these measured values, the temperatures of less accessible machine components are then able to be deduced using physical simulation models.

It is an object of the present invention to specify a method and a machine controller for monitoring the temperature of an electromechanical machine that allow more efficient and/or less complex temperature monitoring.

This object is achieved by means of a method having the features of patent claim 1, by means of a machine controller having the features of patent claim 10, by means of a computer program product having the features of patent claim 11 and by means of a computer-readable storage medium having the features of patent claim 12.

In order to monitor the temperature of an electromechanical machine on the basis of electrical operating data of the machine, structural data relating to a geometry, a thermal conductivity and an electrical conductivity of elements of the machine are read in. In addition, predetermined temperature-critical points of the machine are localized with reference to the structural data. Furthermore, a plurality of temperature profiles in the machine are simulated in a spatially resolved manner on the basis of the structural data by means of a first thermal simulation model comprising a plurality of spatially resolved trial functions. Proceeding from this, a reduced thermal simulation model comprising a plurality of trial functions lower than the first thermal simulation model is generated and set in such a way that it essentially reproduces the temperature profiles specifically at the temperature-critical points. The electrical operating data are then recorded during ongoing operation of the machine, and electrical energy losses in the machine are continuously simulated in a spatially resolved manner by means of an electrical simulation model of the machine on the basis of the structural data and the recorded electrical operating data. Furthermore, temperatures at the temperature-critical points are continuously ascertained by means of the reduced thermal simulation model on the basis of the structural data and the simulated electrical energy losses, and are output in order to monitor the temperature of the machine.

A machine controller, a computer program product and a computer-readable, preferably non-volatile, storage medium are provided in order to carry out the method according to the invention.

By way of example, the method according to the invention and the machine controller according to the invention may be carried out or implemented by means of one or more computers, processors, application-specific integrated circuits (ASICs), digital signal processors (DSPs) and/or what are known as field-programmable gate arrays (FPGAs).

An advantage of the invention can be seen, in particular, in the fact that temperatures prevailing in or on the machine are able to be ascertained on the basis of electrical operating data that are frequently present in a machine controller in any case. In many cases, it is therefore no longer necessary to install temperature sensors on or in the machine itself. In addition, temperatures are also able to be ascertained and/or monitored at points, which are not easily accessible, of the machine, in particular inside the machine, by means of the simulations.

On account of focusing the temperature determination on predetermined temperature-critical points, in many cases it is possible to generate a reduced thermal simulation model that is considerably simplified compared to the first thermal simulation model. Such a reduced thermal simulation model generally requires significantly fewer computing resources. The reduced thermal simulation model is therefore able to be executed in real time in many cases with relatively little computing complexity in order to monitor the machine in real time.

Advantageous embodiments and developments of the invention are specified in the dependent claims.

According to one advantageous embodiment of the invention, an operating current and/or an operating voltage of the machine or a component thereof may be quantified by the electrical operating data. Alternatively or additionally, the electrical operating data may quantify an intermediate circuit voltage, a frequency and/or a degree of modulation. The above electrical operating data are present in many machine controllers in any case, with the result that, often, no additional installations are required on or in the machine to be monitored in order to monitor the temperature of the machine.

According to a further advantageous embodiment of the invention, the trial functions of the reduced thermal simulation model may be selected from the trial functions of the first thermal simulation model and/or parameterized in such a way that a deviation between the temperature profiles ascertained by the reduced thermal simulation model and the temperature profiles ascertained by the first thermal simulation model is minimized specifically at the temperature-critical points. By focusing on the temperature-critical points or disregarding non-critical points, or taking same into consideration in a simplified manner, the number of trial functions required for the reduced thermal simulation model is generally considerably reduced. The reduction process may in particular be carried out in such a way that the deviation is minimized specifically, preferably or exclusively at the temperature-critical points and the minimized deviation does not exceed a predetermined deviation threshold value.

Furthermore, an ambient temperature of the machine and/or an air speed in an environment of the machine may be continuously recorded using sensors. The temperatures at the temperature-critical points may then be ascertained depending on the ambient temperature and/or the air speed. This makes it possible to significantly improve simulation accuracy in many cases.

In addition, mechanical energy losses in the machine may be simulated in a spatially resolved manner by means of a mechanical simulation model of the machine on the basis of the structural data and mechanical operating data of the machine. The temperatures at the temperature-critical points may then be ascertained on the basis of the simulated mechanical energy losses. The mechanical simulation model may in particular simulate friction losses, for example in axle bearings of the machine. For this purpose, the structural data may comprise coefficients of friction for the machine elements affected by friction losses.

Furthermore, the mechanical operating data may quantify a rotational speed, a torque, a speed of movement and/or an exerted force of the machine or a component thereof. Such mechanical operating data are present in many machine controllers in any case, with the result that, often, no additional installations are required on or in the machine to be monitored in order to monitor the temperature of the machine.

According to one advantageous development of the invention, structural data relating to the electrical conductivity and/or the thermal conductivity of the machine elements may be modified depending on the ascertained temperatures. A simulation of the electrical energy losses and/or an ascertainment of the temperatures at the temperature-critical points may then be carried out on the basis of the modified structural data. This in particular makes it possible to take a temperature dependency of electrical resistances into consideration when simulating the electrical energy losses and/or to take a temperature dependency of a thermal conductivity into consideration when ascertaining the temperatures. This makes it possible to generally significantly increase simulation accuracy.

Furthermore, on the basis of the ascertained temperatures at the temperature-critical points, the machine may be regulated down, information concerning an optimized operation of the machine may be output, a recommendation for an optimized operation of the machine may be output, and/or a cooling apparatus may be actuated. In many cases, wear of the machine may be considerably reduced and/or the service life thereof may be increased due to the above measures.

According to a further advantageous embodiment of the invention, a position of a predetermined machine component may be ascertained on the basis of the structural data. The ascertained position may then be used as a temperature-critical point, wherein the ascertained temperature at this position is output as a component-specific temperature value. This makes it possible to individually monitor one or more critical machine components, for example a rotor, a stator, a winding, an axle bearing and/or insulation of an electric motor.

One exemplary embodiment of the invention is explained in more detail below with reference to the drawing, in which, in each case in a schematic representation:

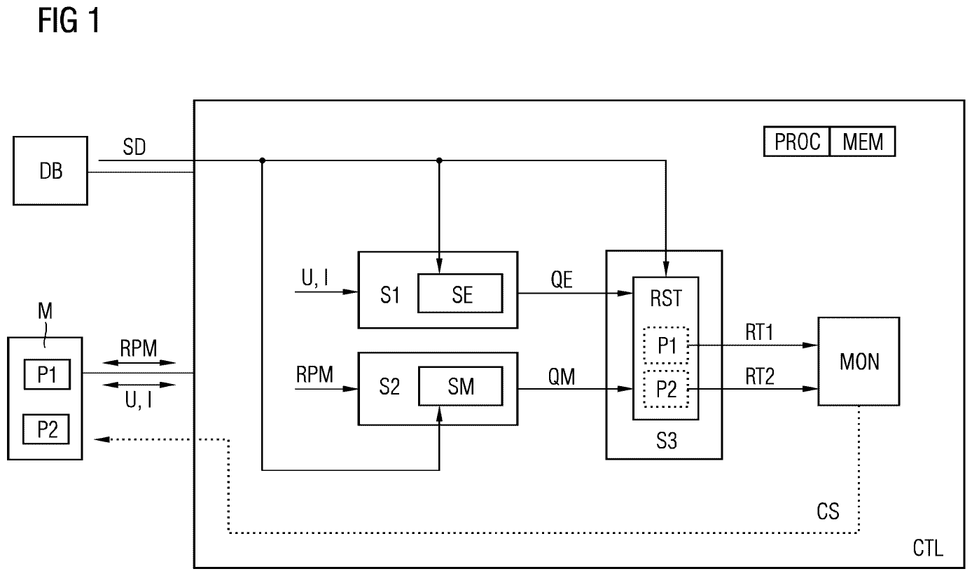

FIG. 1 shows temperature monitoring of an electric motor by a motor controller, and

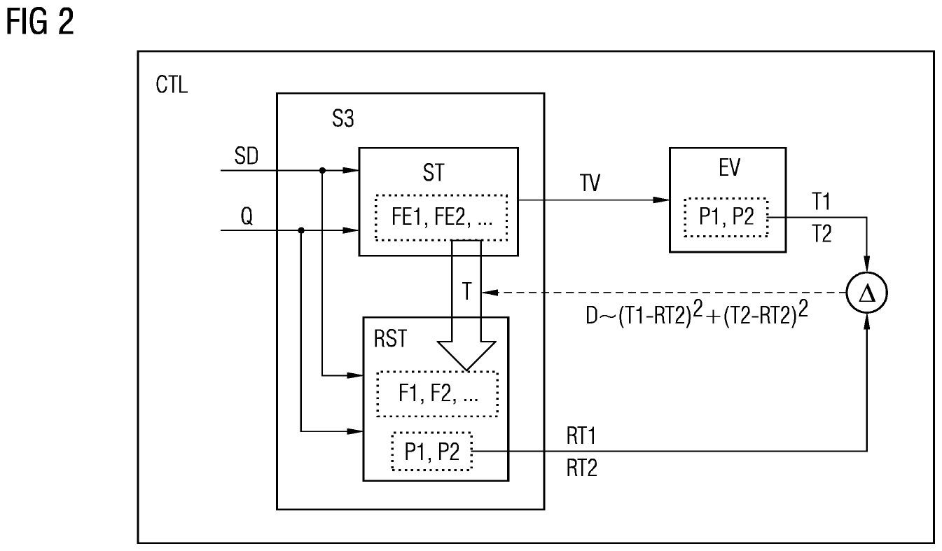

FIG. 2 shows generation of a reduced thermal simulation model for the motor controller.

FIG. 1 illustrates temperature monitoring of an electric motor M in the form of an electromechanical machine by a motor controller CTL in the form of the machine controller according to the invention. Alternatively, the electromechanical machine M to be monitored may also be a robot, a machine tool, a turbine, a production machine, a motor vehicle, a 3D printer or a component thereof, or may comprise such machines or components. The motor controller CTL may in particular comprise an inverter.

In addition, the motor controller CTL has one or more processors PROC for carrying out a method according to the invention and one or more memories MEM for storing data to be processed.

In FIG. 1 the motor controller CTL is shown externally to the electromechanical machine M and is coupled thereto. Alternatively, the motor controller CTL may also be completely or partially integrated into the electromechanical machine M.

The motor controller CTL is used to operate and control the electric motor M. For this purpose, the motor controller CTL may in particular predetermine a motor rotational speed RPM for the electric motor M and/or supply the electric motor M with an appropriate operating voltage U and/or an appropriate operating current I. Energy may be supplied to the electric motor M in particular by an inverter (not shown) of the motor controller CTL. In addition, the motor controller CTL may record motor rotational speeds RPM, operating voltages U and/or operating currents I presently measured by sensors of the electric motor M. For reasons of clarity, measured and predetermined operating data are each designated by the same reference sign in the figures.

Alternatively or additionally to the motor rotational speeds RPM, further mechanical operating data of the electromechanical machine M, for example a torque, a speed of movement and/or an exerted force of the machine M or a component thereof, may be recorded or used by the motor controller CTL. Correspondingly, in addition to the operating voltages U or the operating currents I, further present electrical operating data of the electromechanical machine M or a component thereof may be recorded or used by the motor controller CTL.

For the present exemplary embodiment, it is assumed that the machine M has two temperature-critical points P1 and P2, the temperature of which is to be specifically monitored. In the case of an electric motor, such a temperature-critical point may in particular be a predetermined point of a rotor, of a stator, of a winding, of an axle bearing or of insulation of the electric motor.

In addition to P1 and P2, one or more further temperature-critical points to be monitored may be provided in or on the machine M. For reasons of clarity, however, only the points Pl and P2 are explicitly shown in the figures in a manner representative of all of the temperature-critical points to be monitored.

The motor controller CTL is furthermore coupled to a database DB in which structural data SD relating to a geometry, a thermal conductivity and an electrical conductivity of elements of the machine M are stored. A thermal conductivity may be equivalently expressed or represented by a thermal resistance, and an electrical conductivity by an electrical resistance.

In addition, the structural data SD comprise coefficients of friction for elements of the machine M affected by friction losses. These may in particular be coefficients of friction for friction between a rotor axle and an axle bearing.

Examples of the machine elements described by the structural data SD are in particular machine components such as rotors, stators, windings, axle bearings or insulation of electric motors or parts of such machine components. In particular, machine elements with a specific influence on electrical conduction, on thermal conduction and/or on friction during operation of the machine M are described by the structural data SD. By way of example, these may be coatings, electrical lines, switching elements, thermal bridges or other structural elements of the machine M. The structural data SD specify the thermal conductivity, the electrical conductivity and/or the friction, preferably in spatially resolved form.

The motor controller CTL comprises a first simulation module S1 with an electrical simulation model SE of the machine M, a second simulation module S2 with a mechanical simulation model SM of the machine M and a third simulation module S3 with a reduced thermal simulation model RST of the machine M. The reduced thermal simulation model RST is generated from a predetermined detailed thermal simulation model of the machine M. The generation of the reduced thermal simulation model RST is explained in more detail further below in connection with FIG. 2.

The first simulation module S1 is used for the continuous spatially resolved and time-resolved simulation of electrical energy losses QE in the machine M on the basis of the electrical simulation model SE. The second simulation module S2 is used for the continuous spatially resolved and time-resolved simulation of mechanical energy losses QM in the machine M by means of the mechanical simulation model SM. Finally, the third simulation module S3 is used for the continuous ascertainment of temperatures RT1 and RT2 at the temperature-critical points P1 and P2 by means of the reduced thermal simulation model RST.

The electrical simulation model SE and the mechanical simulation model SM may possibly be combined to form an electromechanical simulation model. The simulation modules S1, S2 and S3 each execute a real-time simulation that runs concurrently during operation of the machine M.

In order to initialize the simulation models SE, SM and RST, the motor controller CTL reads in the structural data SD from the database DB and supplies the read-in structural data SD in each case at least partially to the simulation modules S1, S2 and S3. As a result, the electrical simulation model SE is initialized by structural data SD relating to the geometry and the electrical conductivity of machine elements. Analogously, the mechanical simulation model SM is initialized by structural data SD relating to the geometry and the friction of machine elements. Finally, the reduced thermal simulation model RST is initialized by structural data SD relating to the geometry and the thermal conductivity of machine elements.

In order to execute the above simulations, many efficient physical simulation methods and models are available. In particular, finite element methods may be used for the simulation. It is therefore possible for the electrical simulation model SE, the mechanical simulation model SM, the detailed thermal simulation model and/or possibly the reduced thermal simulation model to each be in the form of a finite element model and to be implemented by means of a plurality of known simulation libraries.

Following the initialization of the simulation models SE, SM and RST, the described simulations may be executed in real time on the basis of the recorded present operating data, in this case U, I and RPM of the machine M. For this purpose, the present electrical operating data, in this case the operating voltage U and the operating current I, are continuously supplied to the first simulation module S1. The first simulation module S1 then continuously simulates the electrical energy losses QE in the machine M in spatially resolved and time-resolved form on the basis of the electrical operating data U and I by means of the initialized electrical simulation model SE. The simulated electrical energy losses QE are supplied to the third simulation module S3 by the first simulation module S1.

Furthermore, the present mechanical operating data, in this case the present rotational speed RPM, are continuously supplied to the second simulation module S2. The second simulation module S2 thus continuously simulates the mechanical energy losses QM in the machine M in spatially resolved and time-resolved form on the basis of the mechanical operating data RPM by means of the initialized mechanical simulation model SM. The simulated mechanical energy losses QM are supplied to the third simulation module S3 by the second simulation module S2.

The energy losses QE and QM obviously act as heat sources in the machine M. The heat from these heat sources is distributed in the machine M according to its local thermal conductivity.

In addition, an ambient temperature and/or an air speed in an environment of the machine M are/is recorded using sensors and likewise supplied to the third simulation module S3.

Finally, the third simulation module S3 continuously ascertains the temperatures RT1 and RT2 at the temperature-critical points P1 and P2 in time-resolved form by means of the initialized reduced thermal simulation model RST on the basis of the simulated, spatially resolved and time-resolved energy losses QE and QM and on the basis of the ambient temperature or air speed.

Preferably, the ascertained temperatures RT1 and RT2 are able to be fed back to the simulation models SE, SM and RST in order to modify the structural data SD on which the models SE, SM and RST are based. This makes it possible to take temperature-dependent electrical resistances into consideration in the electrical simulation model SE, to take temperature-dependent thermal resistances into consideration in the reduced thermal simulation model RST and/or to take temperature-dependent mechanical properties of machine elements into consideration in the mechanical simulation model SM. It is therefore possible to significantly increase accuracy of the simulations in many cases.

The ascertained temperatures RT1 and RT2 are transmitted from the third simulation module S3 to a monitoring module MON of the motor controller CTL. The monitoring module MON continuously checks, on the basis of the transmitted temperatures RT1 and RT2, whether a permissible maximum temperature is being exceeded and/or a respective target temperature is being maintained at the temperature-critical point P1 or P2 in question. This may be done, for example, by a comparison with predetermined threshold values and/or with predetermined temperature intervals.

Depending on these checks, the machine M may be regulated down by the monitoring module MON, a cooling apparatus of the machine M may be actuated and/or information or a recommendation for an optimized operation of the machine M may be output. In order to actuate the machine M accordingly, a suitable control signal CS is formed by the monitoring module MON and—as indicated by a dotted arrow in FIG. 1—transmitted to the machine M.

The invention allows the temperature of the machine or of the motor M to be monitored efficiently and accurately on the basis of presently measured operating data or operating data that are predetermined by the motor controller CTL, in this case U, I, RPM, that are present in many machine controllers, motor controllers or inverters in any case. This makes it possible to implement temperature monitoring that in many cases does not require complex sensors that have to be attached on or in the motor.

In addition, a computing complexity for the thermal simulation may be considerably reduced in many cases by the reduction, which is described below, of a detailed thermal simulation model to the reduced thermal simulation model RST. Insofar as a sufficiently accurate thermal simulation often takes up a significant or dominant proportion of a total computing complexity, this may be significantly reduced in many cases.

FIG. 2 illustrates generation of the reduced thermal simulation model RST for the motor controller CTL from a predetermined detailed thermal simulation model ST. Insofar as the same or corresponding reference signs are used in FIG. 2 as in FIG. 1, these reference signs designate the same or corresponding entities, which may be implemented or configured in particular as described above. Some of the components and data flows of the motor controller CTL and the machine M shown in FIG. 1 are no longer explicitly shown in FIG. 2 for reasons of clarity.

The detailed thermal simulation model ST is implemented in the third simulation module S3 as a finite element model comprising a plurality of spatially resolved trial functions FE1, FE2, . . . . For the implementation, at least some of the structural data SD are supplied to the third simulation module S3. In the context of the finite element model, that region of the machine M for which a thermal simulation is intended to be executed is divided into a plurality of finite spatial elements. In the context of the finite element model, localized trial functions, in this case FE1, FE2, . . . are then defined on these finite spatial elements. The individual trial functions FE1, FE2, . . . are known to describe the behavior to be simulated, in this case a temperature behavior, in a respective finite spatial element. A plurality of efficient program libraries are available for the division into the finite spatial elements, for the configuration of the trial functions FE1, FE2, . . . and for the execution of finite element-based simulations.

In the present case, the division into the finite spatial elements is carried out depending on geometry data of the machine M that are contained in the supplied structural data SD. Proceeding from this, a thermal conduction equation discretized into the finite spatial elements is set up on the basis of spatially resolved data that are contained in the supplied structural data SD and relate to the thermal conductivity of elements of the machine M.

A plurality of known and efficient methods are available for setting up and solving such a discretized thermal conduction equation.

A large number of finite elements are, however, often required for a sufficiently accurate thermal simulation, which generally causes a considerable computing complexity. For this reason, the detailed thermal simulation model ST is transformed by way of a transformation T into a simplified thermal simulation model, in this case RST, comprising a significantly lower number of trial functions F1, F2, . . . .

The reduced thermal simulation model RST is initially geometrically initialized on the basis of the geometry data contained in the supplied structural data SD or on the basis of geometrical structures of the detailed thermal simulation model ST. Furthermore, the temperature-critical points P1 and P2 are localized with reference to the structural data SD. In this case, coordinates of the temperature-critical points P1 and P2 are in particular ascertained with reference to a coordinate system defined in the structural data SD.

Proceeding from this, trial functions F1, F2, . . . that are specifically focused on the temperature-critical points P1 and P2 or adapted thereto are selected and/or configured. The trial functions F1, F2, . . . may be generated from the trial functions FE1, FE2, . . . at least partially by way of the transformation T. When selecting and/or configuring the trial functions F1, F2, . . . , the temperature-critical points P1 and P2 are preferred in comparison to other points of the machine M that are less temperature-critical or have less of an influence on thermal conduction. In many cases, it is possible to considerably reduce the number of trial functions F1, F2, . . . compared to the number of trial functions FE1, FE2, . . . as a result of such thinning of, removing detail from and/or disregarding trial functions at less critical points.

In order to further adjust the reduced thermal simulation model RST, in each case a plurality of spatially resolved and time-resolved energy losses Q that act as heat sources are supplied to said reduced thermal simulation model and to the detailed thermal simulation model ST in the form of input data. By way of example, the energy losses Q may comprise a plurality of recorded or simulated electrical energy losses QE and/or mechanical energy losses QM of the machine M. In addition, ambient temperatures and/or air speeds in an environment of the machine M may also be represented as heat sources or heat sinks by the energy losses Q.

A plurality of respectively associated spatially resolved and time-resolved temperature profiles TV in the machine M are simulated by means of the detailed thermal simulation model ST on the basis of the supplied plurality of energy losses Q. The simulated temperature profiles TV are transmitted from the third simulation module S3 to an evaluation module EV of the motor controller CTL. The evaluation module EV evaluates the temperature profiles TV in each case at the temperature-critical points P1 and P2 and thus ascertains simulated profiles of temperatures T1 and T2 at the temperature-critical points P1 and P2.

Analogously, a plurality of profiles of respectively associated temperatures RT1 and RT2 are ascertained at the temperature-critical points P1 and P2 on the basis of the supplied plurality of energy losses Q by means of the reduced thermal simulation model RST.

The reduced thermal simulation model RST and/or the trial functions F1, F2, . . . thereof are/is now set and/or parameterized in such a way that the temperatures RT1 and RT2 reproduce the temperatures T1 and T2 as accurately as possible. For this purpose, a deviation D of the profiles of the temperatures RT1 and RT2 from the associated profiles of the temperatures T1 and T2 is ascertained. The deviation D may in particular be ascertained as a time integral or as a temporal sum over a magnitude or a square of a difference between a respective temperature pair (RT1, RT2) and the respectively associated temperature pair (T1, T2). By way of example, in accordance with D=integral [(RT1(t)−T1(t))2+(RT2(t)−T2(t))2] dt.

As indicated by the dashed arrows in FIG. 2, the deviation D is fed back to the third simulation module S3. The reduced thermal simulation model RST and/or the trial functions F1, F2, . . . thereof are/is set and/or parameterized on the basis of the deviation D in such a way that the deviation D is minimized. A plurality of efficient optimization methods are available for such minimization problems.

Preferably, the minimal deviation D that is able to be achieved in this way is compared with a predetermined deviation threshold value. As long as the deviation threshold value is not exceeded by the minimal deviation D, the reduction process of the reduced thermal simulation model RST may be continued; in particular by virtue of the trial functions F1, F2, . . . being thinned further, having detail removed or being disregarded.

This makes it possible to considerably simplify the reduced thermal simulation model RST in many cases with a predeterminable accuracy, with the result that a real-time simulation of the thermal behavior of the machine M in many cases only requires relatively few computing resources.

1. A computer-implemented method for monitoring the temperature of an electromechanical machine on the basis of electrical operating data of the machine, wherein
a) structural data relating to a geometry, a thermal conductivity and an electrical conductivity of elements of the machine are read in,
b) predetermined temperature-critical points of the machine are localized with reference to the structural data,
c) a plurality of temperature profiles in the machine are simulated in a spatially resolved manner on the basis of the structural data by a first thermal simulation model having a plurality of spatially resolved trial functions,
d) a reduced thermal simulation model having a plurality of trial functions lower than the first thermal simulation model is generated and set in such a way that it essentially reproduces the temperature profiles specifically at the temperature-critical points,
e) the electrical operating data are recorded during ongoing operation of the machine,
f) electrical energy losses in the machine are continuously simulated in a spatially resolved manner by an electrical simulation model of the machine on the basis of the structural data and the electrical operating data,
g) temperatures at the temperature-critical points are continuously ascertained by the reduced thermal simulation model on the basis of the structural data and the simulated electrical energy losses, and
h) the ascertained temperatures are output in order to monitor the temperature of the machine.

2. The method as claimed in claim 1, wherein an operating current and/or an operating voltage of the machine are/is quantified by the electrical operating data.

3. The method as claimed in claim 1, wherein the trial functions of the reduced thermal simulation model are selected from the trial functions of the first thermal simulation model and/or parameterized in such a way that a deviation between the temperature profiles ascertained by the reduced thermal simulation model and the temperature profiles ascertained by the first thermal simulation model is minimized specifically at the temperature-critical points.

4. The method as claimed in claim 1, wherein an ambient temperature of the machine and/or an air speed in an environment of the machine is continuously recorded using sensors, and in that the temperatures at the temperature-critical points are ascertained depending on the ambient temperature and/or the air speed.

5. The method as claimed in claim 1, wherein mechanical energy losses in the machine are simulated in a spatially resolved manner by a mechanical simulation model of the machine on the basis of the structural data and mechanical operating data of the machine, and in that the temperatures at the temperature-critical points are ascertained on the basis of the simulated mechanical energy losses.

6. The method as claimed in claim 5, wherein a rotational speed, a torque, a speed of movement and/or an exerted force of the machine are/is quantified by the mechanical operating data.

7. The method as claimed in claim 1, wherein structural data relating to the electrical conductivity and/or the thermal conductivity of the machine elements are modified depending on the ascertained temperatures, and in that a simulation of the electrical energy losses and/or an ascertainment of the temperatures at the temperature-critical points are/is carried out on the basis of the modified structural data.

8. The method as claimed in claim 1, wherein, on the basis of the ascertained temperatures at the temperature-critical points,
the machine is regulated down,
information concerning an optimized operation of the machine is output,
a recommendation for an optimized operation of the machine is output, and/or
a cooling apparatus is actuated.

9. The method as claimed in claim 1, wherein a position of a predetermined machine component is ascertained on the basis of the structural data, in that the ascertained position is used as a temperature-critical point, and in that the ascertained temperature at this position is output as a component-specific temperature value.

10. A machine controller for operating, and for monitoring the temperature of an electromechanical machine, comprising means for carrying out the steps of a method as claimed claim 1.

11. A computer program product, comprising a computer readable hardware storage device having computer readable program code stored therein, which, when the program code is executed by a computer, cause the latter to carry out a method as claimed in claim 1.

12. A computer-readable storage medium comprising a computer program product as claimed in claim 11.
